(19) United States
(12) Patent Application Publication
(10) Pub. No.: US 2008/0024697 A1
(43) Pub. Date: Jan. 31, 2008

(54) FLEXIBLE PRINTED CIRCUIT, BACK LIGHT ASSEMBLY, AND LIQUID CRYSTAL DISPLAY INCLUDING THE SAME

(76) Inventors: Wal-Hee KIM, Yongin-si (KR); Se-In Chang, Suwon-si (KR); Sang-Hee Lee, Yongin-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/829,022

(22) Filed: Jul. 26, 2007

(30) Foreign Application Priority Data
Jul. 31, 2006 (KR) 10-2006-0071995

(51) Int. Cl. G02F 1/13357; F21S 2/00; H01L 21/04; H01L 33/00

(52) U.S. Cl. 349/62; 257/99; 362/222; 438/22; 257/E33.057; 257/E21.04

(57) ABSTRACT

A liquid crystal display includes: an LC panel assembly for displaying an image; a backlight assembly 145 for providing light to the LC panel assembly; and at least one optical sheet disposed between the LC panel assembly and the backlight assembly, wherein the backlight assembly comprises at least one flexible printed circuit having a body including the light source and a connection portion separable from the body for connecting the body to a source of power.

### CROSS-REFERENCE TO RELATED APPLICATION

This application claims priority to and the benefit of Korean Patent Application No. 10-2006-000071995 filed in the Korean Intellectual Property Office on Jul. 31, 2006, the entire contents of which are incorporated herein by reference.

### BACKGROUND OF THE INVENTION

1. Field of the Invention

The present invention relates to a flexible printed circuit, a back light assembly, and a liquid crystal display including the same.

2. Description of Related Art

Generally, a liquid crystal display (LCD) includes two panels provided with field-generating electrodes and a liquid crystal (LC) layer having dielectric anisotropy interposed therebetween. The field-generating electrodes are supplied with voltages that apply an electric field across the LC layer which varies the light transmittance of the liquid crystal layer depending on the strength of the applied field to display desired images.

The light for an LCD may be provided by a back lighting unit or by natural light. The back lighting unit for an LCD may include light sources such as cold cathode fluorescent lamps (CCFLs), external electrode fluorescent lamps (EEFLs), or light emitting diodes (LEDs). An optical film is include to provide uniform brightness of the light. A flexible printed circuit (FPC) is used in order to connect the power supply to the lighting unit. Each FPC has a shape to accommodate the respective shape of the various shapes of LCDs. However, when FPCs of various shapes are manufactured, multiple molds are needed and cutting of the FPCs may involve a large amount of waste.

### SUMMARY OF THE INVENTION

According to one aspect of the present invention the product yield of FPCs is improved by effectively arranging a plurality of FPCs on an original substrate.

According to one aspect of the present invention a liquid crystal display includes an LC panel assembly for displaying an image, a back light assembly, and at least one optical sheet disposed between the LC panel assembly and the back light assembly. The back light assembly includes at least one flexible printed circuit including a body for providing the light source and a connector that is separable from the body for connecting the body to an external source.

The body and the connection portion of the flexible printed circuit may be connected to each other through at least one pad, and the body may have a plurality of pads.

A back light assembly includes a light source, at least one flexible printed circuit including a body for providing the light source and a light guide plate for guiding light emitted from the light source to the liquid crystal panel. The back light assembly may further include a reflection sheet positioned at a lower portion of the light guide plate that directs light to the lower portion of the light guide plate.

A method for manufacturing a flexible printed circuit includes arranging a body and a connection portion that is separable from the body on an original substrate, forming a light source on the body, cutting the body and the connection portion from the original substrate; and connecting the connection portion to the body.

### BRIEF DESCRIPTION OF THE DRAWINGS

The present invention will become more apparent by describing preferred embodiments thereof in detail with reference to the accompanying drawings, in which:

FIG. 1 is an exploded perspective view of an LCD according to an embodiment of the present invention;

FIG. 2 is a layout view of an FPC according to an embodiment of the present invention;

FIG. 3 is a layout view showing the arrangement of FPCs of FIG. 2 on an original substrate;

FIGS. 4 to 6 are layout views of an FPC according to another embodiments of the present invention; and

FIG. 7 is a layout view showing the arrangement of FPCs of FIG. 6 on an original substrate.

### DETAILED DESCRIPTION OF EMBODIMENTS

The present invention will be described more fully hereinafter with reference to the accompanying drawings, in which preferred embodiments of the inventions invention are shown.

In the drawings, the thickness of layers and regions are exaggerated for clarity. Like numerals refer to like elements throughout. It will be understood that when an element such as a layer, film, region, substrate, or panel is referred to as being “on” another element, it can be directly on the other element or intervening elements may also be present. In contrast, when an element is referred to as being “directly on” another element, there are no intervening elements present.

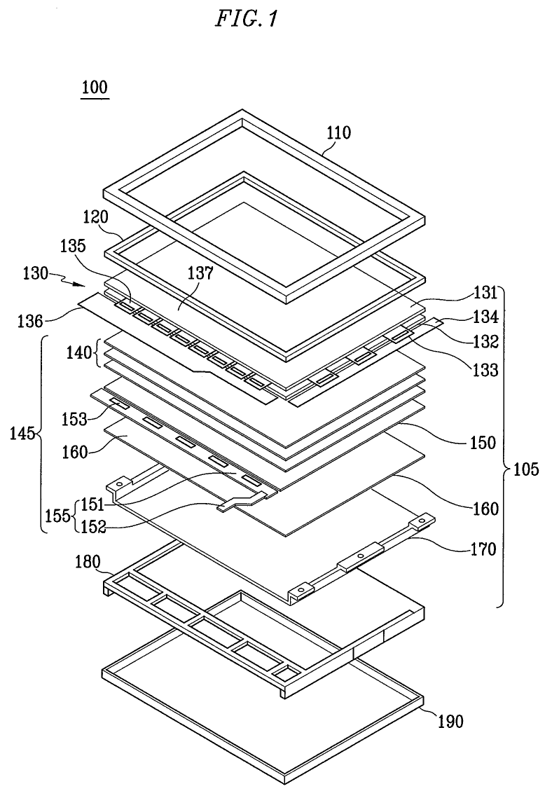

A liquid crystal display according to an embodiment of the present invention is now described in detail with reference to FIG. 1.

FIG. 1 is an exploded perspective view of an LCD according to an embodiment of the present invention.

Referring to FIG. 1, an LCD 100 according to an embodiment of the present invention includes a liquid crystal (LC) module 105, and front and rear cases 110 and 190 for protecting the LC module. LC module 105 includes an LC panel assembly 130 for displaying an image and a backlight assembly 145. LC panel assembly 130 includes an LC display panel 137, a plurality of data tape carrier packets (TCPs) 135, a data printed circuit board (PCB) 136, a plurality of gate TCPs 133, and a gate PCB 134.

LC display panel 137 includes a thin film transistor (TFT) panel 132, a color filter panel 131 facing TFT panel 132, and a liquid crystal layer (not shown) interposed between TFT panel 132 and color filter panel 131.

TFT panel 132 includes a plurality of pixel electrodes (not shown) arranged in a matrix, a plurality of TFTs (not shown) coupled to the pixel electrodes, and a plurality of signal lines including gate lines (not shown) and data lines (not shown) coupled to the TFTs.

The gate lines and the data lines are respectively connected to gate PCB 134 and data PCB 136 via gate TCP 133 and data TCP 135. Accordingly, gate PCB 134 and data PCB 136 receive electrical signals from an external source, and transfer driving signals and control signals to the gate lines and the data lines.

Color filter panel 131 includes pixels of three primary colors (red, green, and blue, or bluish green, claret, and yellow), namely, color pixels that manifest a certain color as light passes therethrough, and typically includes a common electrode made of a transparent material such as indium tin oxide (ITO) on the entire surface thereof. When the TFT switching elements are turned on, an electric field is formed between each pixel electrode and the common electrode. The applied electric field changes the arrangement of liquid crystals between TFT panel 132 and color filter panel 131 that changes the light transmittance of the liquid crystals to display the desired image.

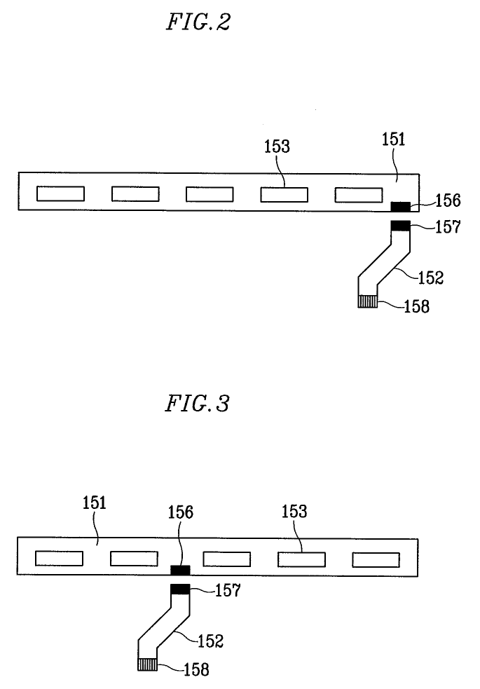

Back light assembly 145 includes a plurality of LEDs 153 for providing light, and a light guide plate 150 for guiding light emitted from LEDs 153 to the LC display panel 137. The LEDs 153 are soldered on flexible printed circuit (FPC) 155. FPC 155 includes a body 151 on which the LEDs 153 are formed and a connection portion 152 for receiving power from an external source. In the embodiment according to the present invention, body 151 and connection portion 152 are electrically connected to and may be separated from each other. This structure will be described in detail with reference to FIG. 2.

Light guide plate 150 is located under LC display panel 137 and guides light emitted from LEDs 153 to LC display panel 137. Light guide plate 150 is sized corresponding to the size of LC display panel 137.

A plurality of optical sheets 140 for changing the luminance characteristics of the light received from the LEDs 153 are provided on light guide plate 150. A reflection sheet 160 is positioned on the entire surface of the lower portion of light guide plate 150 and reflects light emitted from LEDs 153 to maximize light efficiency.

A bottom chassis 170 for receiving LC panel assembly 130 and back light assembly 145 is provided as a receiving container. A molded frame 180 supports bottom chassis 170. The bottom surface of molded frame 180 has a plurality of openings to expose the rear surface of bottom chassis 170 to the outside. Portions of the molded frame 180 corresponding to regions in which gate and data PCBs 134 and 136 are folded and inserted also have a plurality of openings to receive components formed on gate and data PCBs 134 and 136.

Although not shown in FIG. 1, an inverter board for supplying electric power supply to the LEDs 153 and a control board for converting signals are provided at the rear side of bottom chassis 170. The inverter board transforms an external power supply to a constant voltage level, and provides it to LEDs 153. The control board is coupled to gate and data PCBs 134 and 136, and converts analog data signals into digital data signals and provides them to LC display panel 137. The inverter board and the control board are protected by a shield case (not shown) covering them.

A top chassis 120 is provided on LC panel assembly 130 to bend gate and data PCBs 134 and 136 to the external side of mold frame 180 and prevent the LC panel assembly from being released from the bottom chassis 170. Front case 110 and rear case 190 are provided at the front of the top chassis 120 and at the rear of the mold frame 180, respectively, and are combined with each other to thereby form an LCD 100.

The structure of FPC 155 of back light assembly 145 will be described in detail with reference to FIGS. 2 to 6.

As shown in FIG. 2, FPC 155 includes a body 151 and a connection portion 152 that are separable from each other. A plurality of LEDs 153 are adhered to body 151. A first pad 156 is formed on body 151. Connection portion 152 includes a second pad 157 and a third pad 158 that are disposed at respective ends of connection portion 152. The second pad 157 is connected to the first pad 156 of body 151, and the third pad 158 is connected to an external power supply.

Advantageously, body 151 and connection portion 152 may be connected by an additional, thicker connector adapted for use with a liquid crystal display of a size greater than seven inches. To connect body 151 and connection portion 152 to each other, various methods may be provided in addition to the additional connector.

FIG. 3 is a layout view showing the arrangement of the FPCs of FIG. 2 on an original substrate.

As shown in FIG. 3, because body 151 and connection portion 152 of the FPC 155 of FIG. 2 are separable from each other, body 151 and connection portion 152 may be effectively arranged on the original substrate 159 using maximum area. Accordingly, the number of FPCs 155 provided per area of original substrate may be maximized, and the portion of waste except for body 151 and connection portion 152 from the original substrate may be minimized.

The above structure may be compared with one in which the body and the connection portion are made as one unit, as in the conventional FPC, where the long sides of the FPCs are not parallel to the transverse side of the original substrate. When soldering the LEDs on the FPCs, if the long sides of the FPCs are not parallel to the transverse side of the original substrate, the angle of a robot arm for loading the LEDs may deviate from a predetermined position such that faulty products may be frequently generated. However, as shown in FIG. 3, because, in accordance with an aspect of the invention, the long sides of body 151 are parallel to the transverse sides of the original substrate 159, a robot arm for loading the LEDs 153 will be able to move in the direction that is parallel to the transverse sides of the original substrate 159. Accordingly, the faulty products due to alignment errors in loading the LEDs 153 are minimized.

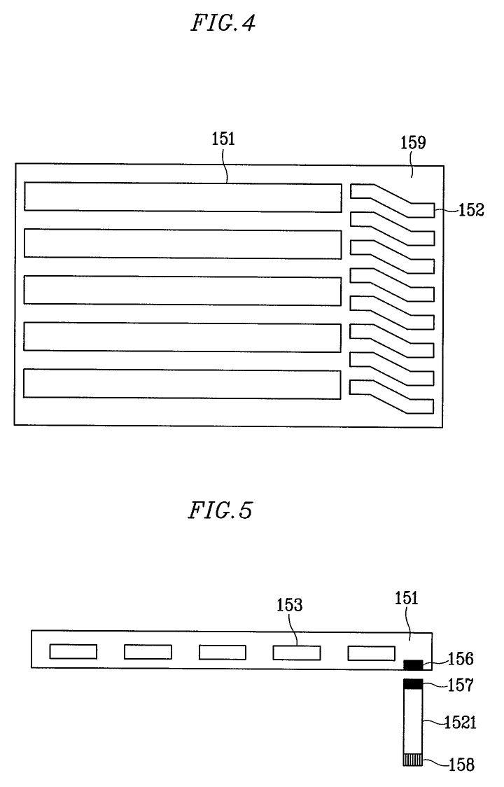

FIGS. 4 and 5 are layout views of FPCs according to other embodiments of the present invention.

As shown in FIG. 4, a first pad 156 of a body 151 for connecting body 151 and a connection portion 152 is disposed in the transverse center of body 151. Also, as shown in FIG. 5, a body 151 includes a plurality of first pads 156 and 1561 for various connections of body 151 and connection portion 152 without regard to position.

When the body and the connection are made as one unit in the conventional FPC, a mold for forming the FPCs must be repeatedly manufactured to accommodate the need for different connection positions. However, because body 151 and connection portion 152 are separable from each other, although the positions of connection portion 152 are changed, it is not necessary have different molds for forming the FPCs.

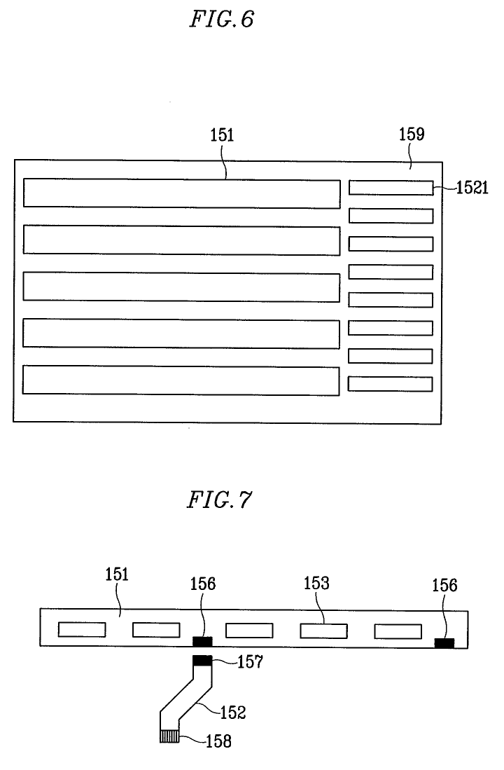

FIG. 6 is a layout view of an FPC according to another embodiment of the present invention, and FIG. 7 is a layout view showing the arrangement of FPCs of FIG. 6 on an original substrate 159.

As shown in FIG. 6, a body 151 and a connection portion 1521 are separable from each other, and connection portion 1521 according to this embodiment in a straight line as opposed to the connectors 152 of FIGS. 2, 4 and 5, which are curved. As shown in FIG. 7, because body 151 and connection portion 1521 are separable from each other, body 151 and connection portion 1521 may be effectively arranged in the original substrate 159 using a maximum area. Accordingly, the number of FPCs provided per area of original substrate may be maximized, and the portion of the waste except for body 151 and connection portion 152 among the original substrate 159 may be minimized.

In the above embodiments, LEDs as the example of the light source is described, however, the separated structure of the body and the connection portion of the present invention may adapt to other light sources. Through the structure of the FPC may be changed according to the structure of the light source, the present invention includes the technique in which the body and the connection portion of the FPCs are separated.

As above-described, the body for soldering the light source and the connection portion for connecting the FPC to an external power supply are separable from each other. Accordingly, when cutting the FPCs from the original substrate, the waste of the original substrate may be minimized and the production yield may be improved, such that the process cost may be decreased.

While the present invention has been described in detail with reference to the preferred embodiments, it is to be understood that the invention is not limited to the disclosed embodiments, but, on the contrary, is intended to cover various modifications and equivalent arrangements included within the sprit and scope of the appended claims.

What is claimed is:

1. A liquid crystal display comprising:
an LC panel assembly for displaying an image;
a backlight assembly for providing light to the LC panel assembly; and
at least one optical sheet disposed between the LC panel assembly and the backlight assembly,
wherein the backlight assembly comprises at least one flexible printed circuit having a body for mounting a light source and a connection portion that is separable from the body for connecting the body to an external source.

2. The liquid crystal display of claim 1, wherein the body and the connection portion of the flexible printed circuit are connected to each other through at least one pad.

3. The liquid crystal display of claim 1, wherein the body and the connection portion of the flexible printed circuit are connected to each other through at least one connector.

4. The liquid crystal display of claim 1, wherein the light source includes light emitting diode (LED).

5. A backlight assembly comprising:
at least one light source for providing light, said light source having an elongated dimension;
at least one flexible printed circuit for forming the light source, the flexible printed circuit having an elongated dimension; and
a light guide plate for guiding light emitted from the light source to a liquid crystal panel,
wherein the flexible printed circuit includes a body for mounting the light source with its elongate dimension parallel to an elongated dimension of the flexible printed circuit and a connection portion that is separable from the body for connecting the body to a source of power.

6. The backlight assembly of claim 5, further comprising: a reflection sheet positioned at a lower portion of the light guide plate and reflecting emitted light to the lower portion of the light guide plate.

7. The backlight assembly of claim 6, wherein the body and the connection portion of the flexible printed circuit are connected to each other through at least one pad.

8. The backlight assembly of claim 5, wherein the light source includes light emitting diode (LED).

9. The backlight assembly of claim 5, wherein the body and the connection portion of the flexible printed circuit are connected to each other through at least one connector.

10. A flexible printed circuit comprising:
a light source for providing light;
a body for providing the light source, and
a connection portion that is separable from the body for connecting the body to an external source.

11. The flexible printed circuit of claim 10, wherein the body and the connection portion are connected to each other through at least one pad.

12. The flexible printed circuit of claim 10, wherein the light source includes light emitting diode (LED).

13. The flexible printed circuit of claim 10, wherein the body and the connection portion are connected to each other through at least one additional connector.

14. A method for manufacturing a flexible printed circuit, comprising:
arranging a body and a connection portion that is separable from the body in an original substrate;
forming a light source on the body;
cutting the body and the connection portion from the original substrate; and
connecting the connection portion to the body.

15. The method of claim 14, wherein the body and the connection portion are connected to each other through at least one pad.

16. The method of claim 15, wherein the light source includes light emitting diode (LED).

17. The method of claim 14, wherein the body and the connection portion are connected to each other through at least one additional connector.
